(19) United States
(12) Patent Application Publication
(10) Pub. No.: US 2026/0235521 A1
(43) Pub. Date: Aug. 13, 2026

(54) SINGLE CRYSTAL QUANTUM DOTS SERS CHIP

(71) Applicant: National University of Singapore, Singapore (SG)

(72) Inventors: Andrivo RUSYDI, Singapore (SG); Bin Leong Edwin ONG, Singapore (SG); Shermine HO, Singapore (SG); Eng Soon TOK, Singapore (SG)

(21) Appl. No.: 19/154,615

(22) PCT Filed: Feb. 5, 2024
(86) PCT No.: PCT/SG2024/050062

§ 371 Date: Aug. 7, 2025

(30) Foreign Application Priority Data
Feb. 8, 2023 (SG) 10202300308Q

(51) Int. Cl. G01N 21/65; C30B 29/02; C30B 29/16; C30B 29/32; C30B 29/52

(52) U.S. Cl. CPC G01N 21/658; C30B 29/02; C30B 29/16; C30B 29/32; C30B 29/52

(57) ABSTRACT

The present disclosure provides a surface-enhanced Raman spectroscopy (SERS) chip The SERS chip comprises a substrate and an array of quantum dots formed on the substrate. The substrate is made of single crystal oxide with a crystal direction (001) perpendicular to a main surface of the substrate. The quantum dots are made of a single crystal material selected from the group consisting of Au, Ag, Cu, Pt, Fe, Co, Ni, Ru, Rh, Pd, and an alloy thereof. The array of quantum dots has an average thickness equal to or less than 3.0±0.5 nm and gaps between adjacent quantum dots of 0.5 nm to 5 nm. The SERS chip exhibits high performance in detection of chiral molecules.

### TECHNICAL FIELD

The present disclosure relates to a Surface-Enhanced Raman Spectroscopy (SERS) chip and in particular, the present disclosure relates to a single crystal quantum dots SERS chip.

### BACKGROUND

SERS is a detection technique for chemical and biological sensing applications. As specimen holders, SERS chips can greatly enhance the intensity of Raman spectral signals to facilitate precise spectrum analysis. However, the microstructures and/or nanostructures on conventional SERS chips have complex arrangement, e.g., surface-modification, chemical functionalization or encapsulation. Besides, methods of fabricating the conventional SERS chips are complicated and tedious.

### SUMMARY

In one aspect, the present disclosure provides a surface-enhanced Raman spectroscopy (SERS) chip. The SERS chip comprises a substrate and an array of quantum dots formed on the substrate. The substrate is made of single crystal oxide with a crystal direction (001) perpendicular to a main surface of the substrate. The quantum dots are made of a single crystal material selected from the group consisting of Au, Ag, Cu, Pt, Fe, Co, Ni, Ru, Rh, Pd, and an alloy thereof. The array of quantum dots has an average thickness equal to or less than 3.0±0.5 nm and gaps between adjacent quantum dots of 0.5 nm to 5 nm.

In some embodiments, the array of quantum dots is characterized by a surface plasmon resonance absorbance peak at a Raman laser wavelength.

In some embodiments, the array of quantum dots has a spin-polarization of 95% in a Raman scattering range of 0 eV to 0.25 eV.

According to some embodiments, the array of quantum dots has a surface plasmon resonance absorbance peak at 633 nm.

According to some embodiments, the surface-enhanced Raman spectroscopy chip, wherein the array of quantum dots is characterized by 6s band hybridized with 5d band and a band gap of 1.75 eV.

In some embodiments, the surface-enhanced Raman spectroscopy chip, wherein the quantum dots demonstrate half metallicity.

In some embodiments, the surface-enhanced Raman spectroscopy chip, wherein the quantum dots are made of single crystal Au with a crystal direction (111) perpendicular to the main surface of the substrate.

According to some embodiments, the surface-enhanced Raman spectroscopy chip, wherein the array of quantum dots has an average diameter of 4 nm to 8 nm along a direction parallel to the main surface of the substrate.

In some embodiments, the surface-enhanced Raman spectroscopy chip, wherein the alloy is a binary alloy.

In some embodiments, the surface-enhanced Raman spectroscopy chip, wherein the alloy is a ternary alloy.

In some embodiments, the surface-enhanced Raman spectroscopy chip, wherein the alloy is a quaternary alloy.

In some embodiments, the surface-enhanced Raman spectroscopy chip, wherein the quantum dots have a crystal orientation deflection within ±0.5 degree.

In some embodiments, the surface-enhanced Raman spectroscopy chip, wherein the oxide is one of MgO and SrTiO₃.

### BRIEF DESCRIPTION OF DRAWINGS

FIG. 1 illustrates a perspective view of a SERS chip according to one embodiment of the present disclosure.

FIG. 2 illustrates an atomic force microscope image of the SERS chip of FIG. 1.

FIG. 3A illustrates a diameter distribution of the Au quantum dots of the SERS chip of FIG. 1.

FIG. 3B illustrates a height distribution of the Au quantum dots of the SERS chip of FIG. 1.

FIG. 4 illustrates an X-ray diffraction pattern of the SERS chip of FIG. 1.

FIG. 5 illustrates a UV-Visible absorbance spectra of the Au quantum dots of the SERS chip of FIG. 1.

FIG. 6 illustrates a device for SERS acquisition with SERS chip of FIG. 1

FIG. 7A illustrates a Raman spectrum of the SERS chip of FIG. 1 with Au quantum dots having an average thickness equal to or less than 3±0.5 nm.

FIG. 7B illustrates degrees of spin polarization of a substrate of the SERS chip of FIG. 1 and the Au quantum dots of the SERS chip of FIG. 1 fabricated at two different temperatures, the Au quantum dots having an average thickness equal to or less than 3±0.5 nm.

FIG. 8A illustrates SERS spectra of crystal-violet on the SERS chip of FIG. 1 fabricated at two different temperatures with Au quantum dots having an average thickness equal to or less than 3±0.5 nm.

FIG. 8B illustrates the magnified region of FIG. 8A.

FIG. 9A illustrates the real part and the imaginary part of the complex dielectric function obtained from spectroscopic ellipsometry of the SERS chip of FIG. 1 with Au quantum dots having an average thickness equal to or less than 3±0.5 nm.

FIG. 9B illustrates the calculated loss function and the reflectivity of the SERS chip of FIG. 1 with Au quantum dots having an average thickness equal to or less than 3±0.5 nm.

FIG. 9C illustrates density of states of spin-up and spin-down states of the Au 5d and 6s bands of the SERS chip of FIG. 1 with Au quantum dots having an average thickness equal to or less than 3±0.5 nm.

FIG. 10A illustrates the real part and the imaginary part of the complex dielectric function obtained from spectroscopic ellipsometry of the SERS chip of FIG. 1 with Au quantum dots having an average thickness greater than 3±0.5 nm.

FIG. 10B illustrates the calculated loss function and the reflectivity of the SERS chip of FIG. 1 with Au quantum dots having an average thickness greater than 3±0.5 nm.

FIG. 10C illustrates Raman spectra of the SERS chip of FIG. 1 with Au quantum dots having an average thickness greater than 3±0.5 nm.

FIG. 10D illustrates SERS spectra of crystal-violet on the SERS chip of FIG. 1 with Au quantum dots having an average thickness greater than 3±0.5 nm.

FIG. 11 illustrates a method of fabricating a SERS chip according to one embodiment of the present disclosure.

FIG. 12 illustrates a perspective view of a SERS wipe according to one embodiment of the present disclosure.

FIG. 13 illustrates a method of fabricating the SERS wipe of FIG. 12.

### DETAILED DESCRIPTION

In the following description, numerous specific details are provided to give a thorough understanding of embodiments. One skilled in the relevant art will recognize, that the various embodiments be practiced without one or more of the specific details, or with other methods, components, materials, etc. In other instances, some or all known structures, materials, or operations may not be shown or described in detail to avoid obfuscation.

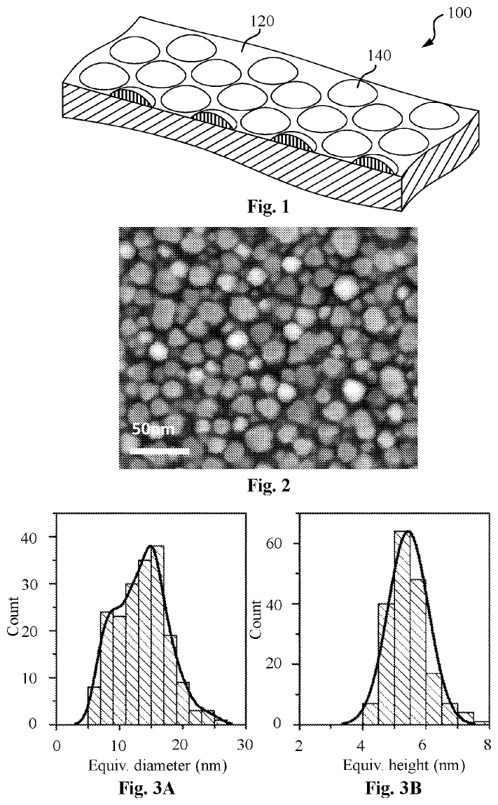

In one aspect, the present disclosure provides a SERS chip 100, as is shown in FIG. 1. The SERS chip 100 includes a substrate 120 and a single crystal nanostructure 140 on the substrate 120. The substrate 120 or at least a surface of the substrate 120 on which the nanostructure 140 is formed is made of a single crystal material selected from the group consisting of Si, Ge, Sn, MgO, TiO₂, SrTiO₃, and LaAl₂O₃. The crystal orientation difference of the single crystal material is within ±0.5 degree. The nanostructure 140 is made of a single crystal material selected from the group consisting of Au, Ag, Cu, Pt, Fe, Co, Ni, Ru, Rh, Pd, and an alloy thereof. The substrate 120 and the nanostructure 140 are symmetry-matching and lattice-matching with one another. The lattice-mismatch between the substrate 120 and the nanostructure 140 is lower than 4%.

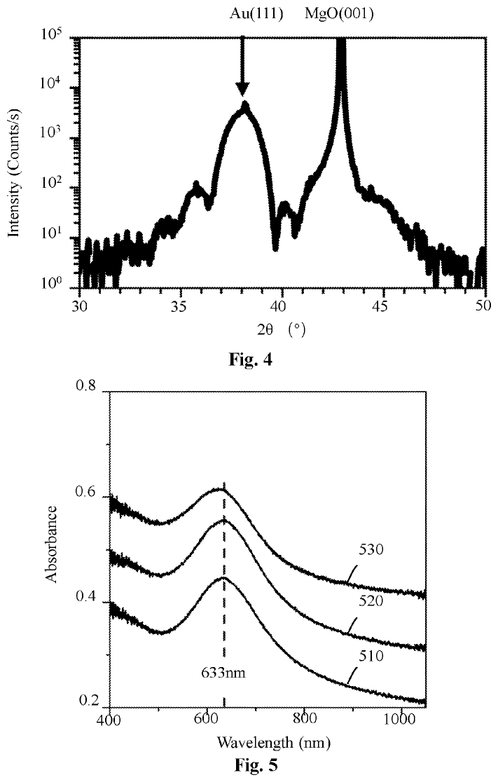

The substrate 120 is made of an oxide. In one embodiment, the substrate 120 is made of MgO (001) and the nanostructure 140 are made of highly oriented Au quantum dots (QDs). Alternatively, the substrate 120 is made of Strontium Titanate (SrTiO₃ or STO in short). In the context, the term “highly oriented quantum dots” refers to quantum dots have a crystal orientation deflection within ±0.5 degree. The expression “MgO (001)” refers to the crystal direction (001) of MgO being parallel to a main surface of the substrate 120. An Atomic Force Microscope (AFM) image shows that the Au QDs have a relatively narrow diameter distribution ranging from ~3 nm to ~30 nm and a height distribution ranging from ~3 nm to ~8 nm, as is shown in FIG. 2, FIG. 3A, and FIG. 3B. The median diameter and the median height of the Au QDs are ~13 nm and ~5 nm, respectively. The average diameter and the average height of the Au QDs are 12.6±4.7 nm and 5.4±0.6 nm, respectively. There are gaps of ~0.5 nm to ~5 nm between the adjacent Au QDs. The Au QDs are single crystalline and arc self-organized or self-assembled with a dominant crystal direction Au (111), as is shown in the X-ray diffraction (XRD) patten of FIG. 4. The XRD pattern also shows the crystal direction MgO (001). As is shown in FIG. 5, plots 510, 520, and 530 represent the UV-Visible spectra of the Au QDs fabricated at 350° C., 450° C., and 550° C., respectively. All of the Au QDs give a Surface Plasmon Resonance absorbance peaks at about 633 nm under the UV-Visible spectroscopy. The details about the fabrication of the Au QDs at various temperatures will be discussed later in this disclosure. The absorbance peak at about 633 nm of the Au QDs is equal to the Raman laser wavelength of 633 nm. It should be appreciated that the Raman laser wavelength can be alternatively configured as any other suitable values, e.g., 638 nm, 785 nm, or 1064 nm. It should also be appreciated that the Au QDs can be configured, e.g. sized, such that the wavelength at their absorbance peak is equal to the Raman laser wavelength.

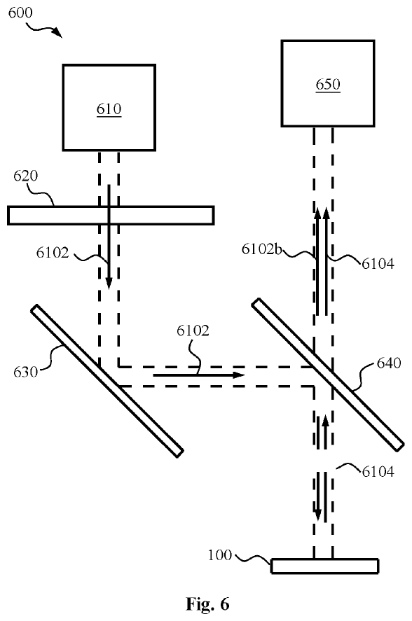

FIG. 6 shows a device for SERS acquisition using the SERS chip 100. The device 600 includes a laser source 610, a polarizer 620, a mirror 630, a beam splitter 640, and a detector 650. The laser source 610 emits a laser with a wavelength of 633 nm travelling along the path 6102 and 6104. The polarizer 620 is a linear, left-circular, or right-circular polarizer. The beam splitter 640 splits the laser reflected by the mirror 630 into two beams. In particular, one of the two beams is reflected to the SERS chip 100 along the path 6102a and the other beam is directed to the detector 650 along the path 6102b. The beam reflected to the SERS chip 100 is further reflected/scattered by the SERS chip 100 and directed to the detector 650 through the beam splitter 640 along the path 6104. The detector 650 acquires the beams travelling along the path 6102b and the path 6104 or the information derived from the beams, e.g., interference, such that the characteristic information of the SERS chip 100, e.g., a Raman spectrum, is derived. Upon a sample to be tested is collected on the SERS chip 100, the characteristic information of the sample 100 is obtained.

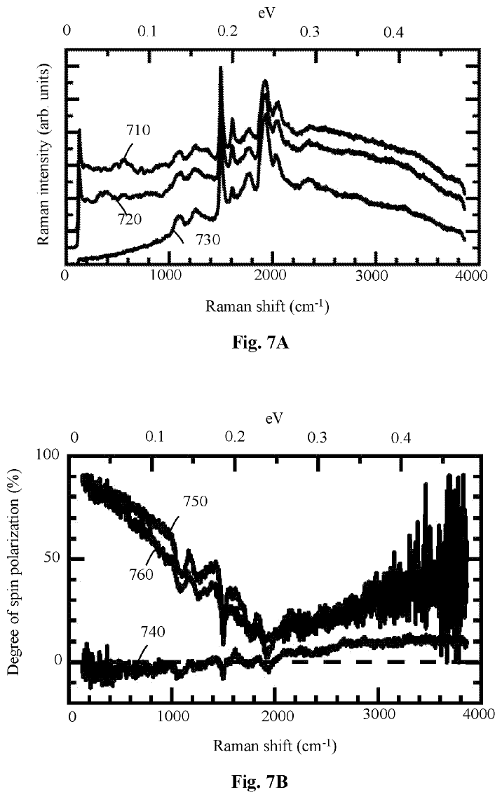

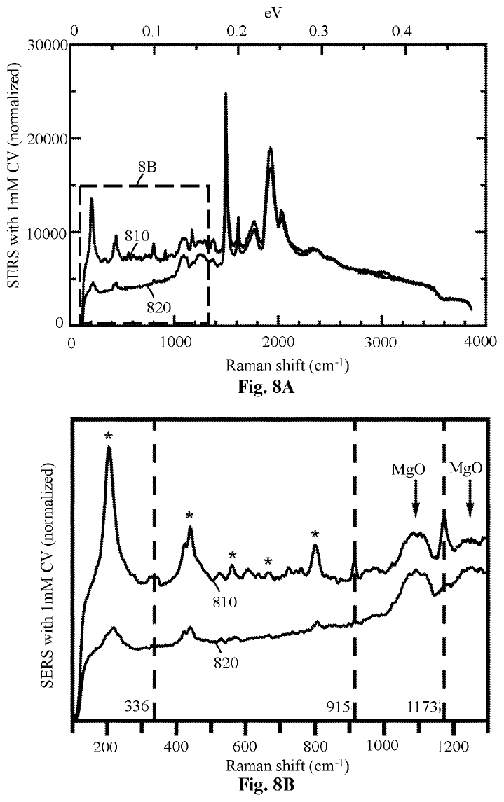

FIG. 7A shows the Raman spectra of the SERS chip 100 using the device of FIG. 6 with the Au QDs 140 fabricated at 550° C. on the substrate 120 of MgO (001), in which the Au quantum dots have an average thickness equal to or less than 3±0.5 nm. Plots 710, 720, and 730 represent the Raman spectrum with the polarizer 620 of linear without circular polarization (LnP), left-circularly polarization (LCP), and right-circularly polarization (RCP), respectively. FIG. 7B shows the degree of spin polarization of the substrate 120 of MgO (001) and the SERS chip 100, where plot 740, 750, and 760 represents the substrate 120 of MgO (001), the SERS chip with the Au QDs 140 fabricated at 350° C., and the SERS chip with the Au QDs 140 fabricated at 550° C., respectively, in which the Au quantum dots have an average thickness equal to or less than 3±0.5 nm. Plot 750 and plot 760 are characterized with the degrees of spin polarization of up to 95% in the 0-0.25 eV Raman scattering range, which are higher than plot 740 and Au nanoparticles that are commercially available.

As an example, 1 mM crystal violet (CV) is applied as a sample collected on the SERS chip 100 with the Au QDs 140 fabricated at 350° C., in which the Au quantum dots have an average thickness equal to or less than 3±0.5 nm. FIG. 8A shows the SERS spectrum of CV on the SERS chip 100 and FIG. 8B shows an enlarged region of the spectrum. Plot 810 and plot 820 represent the spectrum using an LCP polarizer and an RCP polarizer, respectively. Plot 810 is characterized with enhanced SERS signal in comparison to plot 820 especially in the 0-0.15 eV Raman scattering range, where the enhanced peaks of CV on plot 810 is marked with asterisks and the peaks of MgO show no observable difference between plot 810 and plot 820. Besides, the peaks at 336 cm⁻¹, 915 cm⁻¹ and 1173 cm⁻¹ of plot 810 are not discernible on plot 820. As such, the SERS chip 100 is suitable for chiral-plasmonic applications in detection of chemical molecules such as CV using as little as 1 mM CV.

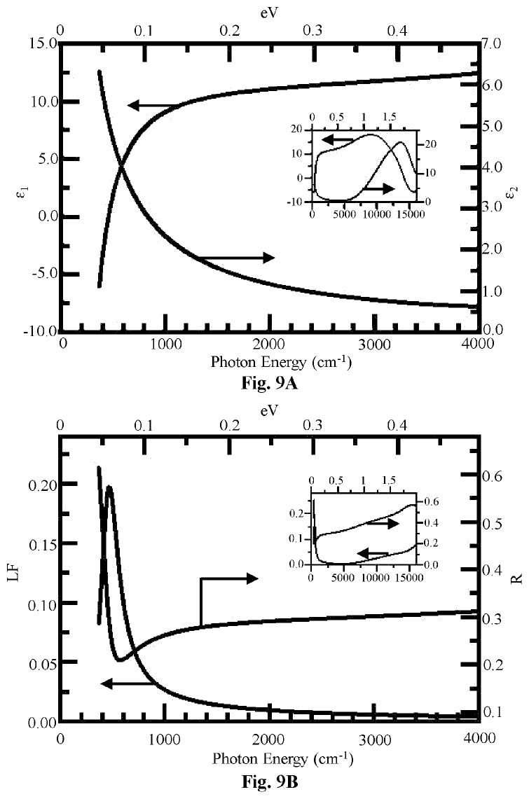

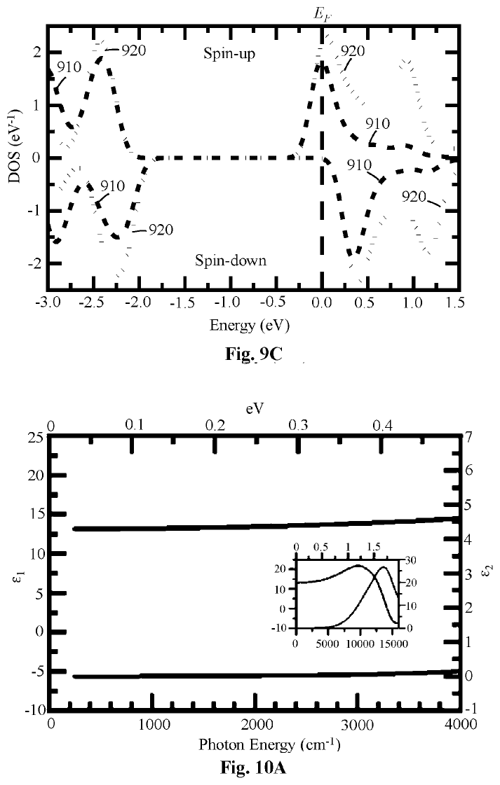

The Au QDs 140 of the SERS chip 100 are characterized with half metallicity, i.e., the Au QDs 140 are metallic along one spin-direction while insulating along the other spin-direction. In comparison, conventional material systems with half metallicity include oxides, sulphides or Hcusler alloys. FIG. 9A, FIG. 9B, and FIG. 9C show the complex dielectric function of the Au QDs 140 obtained from Spectroscopic Ellipsometry. In FIG. 9A, the finite but positive low-energy ε₁ is attributed to strong electronic correlations while the sharp Drude-like response of low-energy 82, along with spin-splitting of 6s band yielding spin-polarized Mottness at ~1.75 cV shows the half metallicity in 6s band strongly hybridized with 5d band and a ~1.75 eV band gap. As is shown in FIG. 9C where plot 910 represents 5d band and plot 920 represents 6s band, this is consistent with the first-principle calculations of Au (3×3×1) (“3×3×1” denotes a volume consisting of 3 unit cells×3 unit cells×1 unit cell) on MgO (3×3×1) where the spin-polarization density of states (s-DOS) shows half metallicity in 6s band strongly hybridized with 5d band and a ~1.75 eV band gap revealing HOSG-QDs/MgO as a new half-metal based on s-band. In FIG. 9B, the half-metal s-band, the peak ~463 nm in the loss function (LF) is attributed to electrons in 6s (spin up) band (or spin majority band) interacting only with LCP leading to a half-metal chiral plasmon.

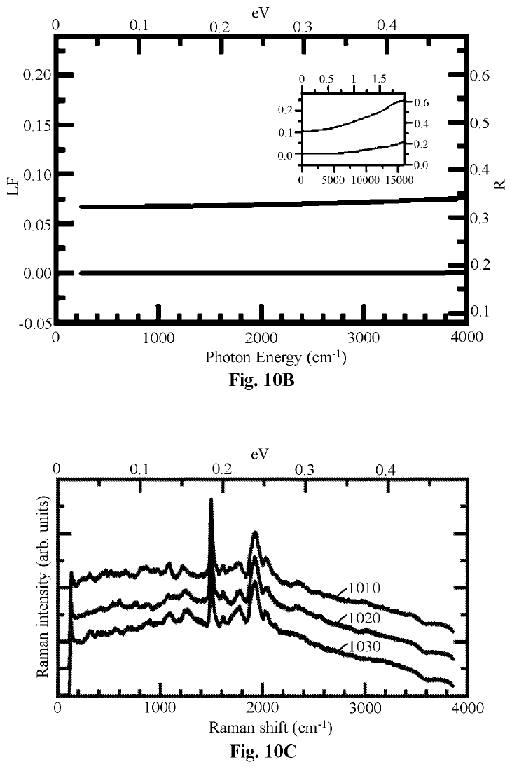

The Au QDs 140 of the SERS chip 100 with an average thickness greater than 3±0.5 nm are not characterized with half metallicity and chiral plasmon excitons, as is shown in FIG. 10A and FIG. 10B. In FIG. 10C, plots 1010, 1020, and 1030 represent the Raman spectrum of the SERS chip 100 with Au QDs 140 fabricated at 350° C. under LnP, LCP, and RCP, respectively. There is no significant contrast between plot 1020 and plot 1030. In FIG. 10D, plots 1040, 1050, and 1060 represent the Raman spectrum of 1 mV CV on the SERS chip 100 with Au QDs 140 fabricated at 350° C. under LnP, LCP, and RCP, respectively. There is no significant contrast between plot 1050 and plot 1060.

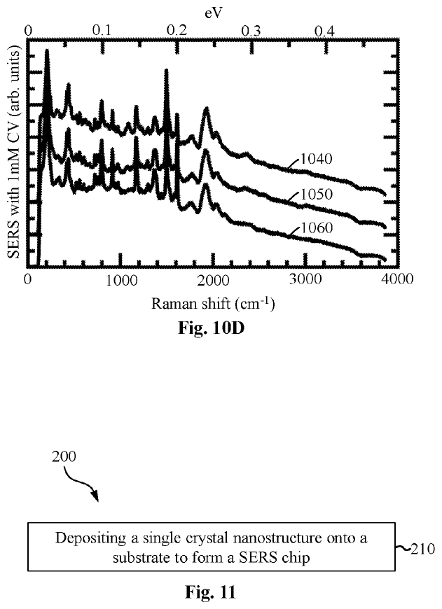

In another aspect, the present disclosure provides a method 200 of fabricating a SERS chip, as is shown in FIG. 11. The method 200 includes depositing a single crystal nanostructure onto a substrate to form a SERS chip. The substrate is made of a single crystal material selected from the group consisting of Si, Ge, Sn, MgO, TiO₂, SrTiO₃, and LaAl₂O₃. The crystal orientation difference of the single crystal material is within ±0.5 degree. The nanostructure 140 is made of a single crystal material selected from the group consisting of Au, Ag, Cu, Pt, Fe, Co, Ni, Ru, Rh, Pd, and an alloy thereof. The substrate and the nanostructures are symmetry-matching and lattice-matching with one another. The lattice-mismatch between the substrate and the nanostructures is lower than 4%. The step of depositing 210 a single crystal nanostructure onto a substrate is performed at elevated temperatures ranging from 300° C. to 900° C., e.g., 350° C., 450° C., or 550° C.

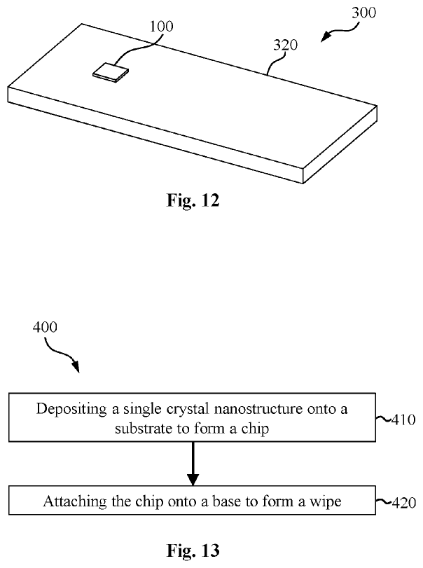

In a third aspect, the present disclosure provides a SERS wipe 300, as is shown in FIG. 12. The SERS wipe includes a base 320 and the SERS chip 100 disposed on the base 320. The base 320 is configured to be easy for handling so as to facilitate disposing samples onto the SERS chip 100. The base 320 can be made of any suitable materials, e.g., glass.

In a fourth aspect, the present disclosure introduces a method 400 of fabricating a SERS wipe. As is shown in FIG. 13, the method 400 includes depositing 410 a single crystal nanostructure onto a substrate and attaching 420 the substrate onto a base to form a SERS chip. The substrate is made of a single crystal material selected from the group consisting of Si, Ge, Sn, MgO, TiO₂, SrTiO₃, and LaAl₂O₃. The crystal orientation difference of the single crystal material is within ±0.5 degree. The nanostructure 140 is made of a single crystal material selected from the group consisting of Au, Ag, Cu, Pt, Fe, Co, Ni, Ru, Rh, Pd, and an alloy thereof. The substrate and the nanostructures are symmetry-matching and lattice-matching with one another. The lattice-mismatch between the substrate and the nanostructures is lower than 4%. The step of depositing 410 a single crystal nanostructure onto a substrate is performed at elevated temperatures ranging from 300° C. to 900° C., e.g., 350° C., 450° C., and 550° C. The method 400 further includes attaching 420 the SERS chip onto a base to form a SERS wipe. The base can be made of any suitable materials, e.g., glass.

All examples described herein, whether of apparatus, methods, materials, or products, are presented for the purpose of illustration and to aid understanding, and are not intended to be limiting or exhaustive. Various changes and modifications may be made by one of ordinary skill in the art without departing from the scope of the invention.

1. A surface-enhanced Raman spectroscopy chip, comprising:
a substrate, the substrate being made of single crystal oxide with a crystal direction (001) perpendicular to a main surface of the substrate; and
an array of quantum dots formed on the substrate, the quantum dots being made of a single crystal material selected from the group consisting of Au, Ag, Cu, Pt, Fe, Co, Ni, Ru, Rh, Pd, and an alloy thereof, wherein the array of quantum dots has an average thickness equal to or less than 3.0 ±0.5 nm and gaps between adjacent quantum dots of 0.5 nm to 5 nm.

2. The surface-enhanced Raman spectroscopy chip of claim 1, wherein the array of quantum dots is characterized by a surface plasmon resonance absorbance peak at a Raman laser wavelength.

3. The surface-enhanced Raman spectroscopy chip of claim 2, wherein the array of quantum dots has a spin-polarization of 95% in a Raman scattering range of 0 eV to 0.25 eV.

4. The surface-enhanced Raman spectroscopy chip of claim 3, wherein the array of quantum dots has a surface plasmon resonance absorbance peak at 633 nm.

5. The surface-enhanced Raman spectroscopy chip of claim 4, wherein the array of quantum dots is characterized by 6s band hybridized with 5d band and a band gap of 1.75 eV.

6. The surface-enhanced Raman spectroscopy chip of claim 5, wherein the quantum dots demonstrate half metallicity.

7. The surface-enhanced Raman spectroscopy chip of claim 1, wherein the quantum dots are made of single crystal Au with a crystal direction (111) perpendicular to the main surface of the substrate.

8. The surface-enhanced Raman spectroscopy chip of claim 7, wherein the array of quantum dots has an average diameter of 4 nm to 8 nm along a direction parallel to the main surface of the substrate.

9. The surface-enhanced Raman spectroscopy chip of claim 8, wherein the alloy is a binary alloy.

10. The surface-enhanced Raman spectroscopy chip of claim 8, wherein the alloy is a ternary alloy.

11. The surface-enhanced Raman spectroscopy chip of claim 8, wherein the alloy is a quaternary alloy.

12. The surface-enhanced Raman spectroscopy chip of claim 8, wherein the quantum dots have a crystal orientation deflection within ±0.5 degree.

13. The surface-enhanced Raman spectroscopy chip of claim 12, wherein the oxide is one of MgO and SrTiO₃.
